(19) United States
(12) Patent Application Publication
(10) Pub. No.: US 2025/0149346 A1
(43) Pub. Date: May 8, 2025

(54) METHOD OF FORMING ELECTROMAGNETIC-WAVE SHIELD, METHOD OF MANUFACTURING STRUCTURE, AND STRUCTURE

(71) Applicants: Hideo NAKAMORI, Shizuoka (JP); Tomoo FUKUDA, Tokyo (JP); Yukihiro WAKABAYASHI, Kanagawa (JP); Kohji TAKEUCHI, Kanagawa (JP); Yohei SHIREN, Tokyo (JP); Takashi FUJITA, Kanagawa (JP); Hiroyuki HIRATSUKA, Kanagawa (JP); Asato TAMURA, Tokyo (JP); Tohru HASEGAWA, Kanagawa (JP)

(72) Inventors: Hideo NAKAMORI, Shizuoka (JP); Tomoo FUKUDA, Tokyo (JP); Yukihiro WAKABAYASHI, Kanagawa (JP); Kohji TAKEUCHI, Kanagawa (JP); Yohei SHIREN, Tokyo (JP); Takashi FUJITA, Kanagawa (JP); Hiroyuki HIRATSUKA, Kanagawa (JP); Asato TAMURA, Tokyo (JP); Tohru HASEGAWA, Kanagawa (JP)

(21) Appl. No.: 18/835,033

(22) PCT Filed: Mar. 13, 2023
(86) PCT No.: PCT/IB2023/052382

§ 371 Date: Aug. 1, 2024

(30) Foreign Application Priority Data
Mar. 17, 2022 (JP) 2022-042254
Nov. 30, 2022 (JP) 2022-191226

(51) Int. Cl. H01L 21/56; H01L 23/31; H01L 23/552

(52) U.S. Cl. CPC H01L 21/56; H01L 23/3192; H01L 23/552

(57) ABSTRACT

A method of forming an electromagnetic-wave shield includes forming a conductive layer and forming an insulating layer. The forming the conductive layer forms a conductive layer having a plurality of openings onto an upper face and a side face of a surface of an object. The forming the insulating layer forms an insulating layer that is continuous from a surface of the conductive layer to the surface of the object through the plurality of openings and adheres to the surface of the object.

### TECHNICAL FIELD

The present disclosure relates to a method of forming an electromagnetic-wave shield, a method of manufacturing a structure, and the structure.

### BACKGROUND ART

Patent Literature 1 (PTL 1) describes a semiconductor integrated circuit that is mounted on a printed circuit board with a wiring pattern formed thereon and is connected to the wiring pattern through a plurality of terminals. The semiconductor integrated circuit includes a shielding portion for shielding electromagnetic-wave noise, the shielding portion being provided to cover the face of the semiconductor integrated circuit on a side opposite to the printed circuit board, and a connector for connecting the shielding portion and a ground on the printed circuit board.

Patent Literature 2 (PTL 2) describes an electromagnetic interface (EMI) shield with a conductive layer including inkjet print.

Patent Literature 3 (PTL 3) describes an electromagnetic-wave shield material 1 includes a (polyethylene terephthalate) PET base material layer, an undercoat layer, an ink receiving layer 6, and a latticed electromagnetic-wave shield mesh layer. The undercoat layer and the ink receiving layer are provided on one face of the PET base material layer. The latticed electromagnetic-wave shield mesh layer formed by screen printing and firing a conductive paste ink is provided on the ink receiving layer.

### CITATION LIST

### Patent Literature

[PTL 1]
Japanese Unexamined Patent Application No. 2001-127211
[PTL 2]
U.S. Pat. No. 9,282,630
[PTL 3]
Japanese Patent No. 5703050

### SUMMARY OF INVENTION

### Technical Problem

An object of the present disclosure is to enhance shielding performance and durability of an electromagnetic-wave shield.

### Solution to Problem

According to an embodiment of the present disclosure, a method of forming an electromagnetic-wave shield includes forming a conductive layer and forming an insulating layer. The forming the conductive layer forms a conductive layer having a plurality of openings onto an upper face and a side face of a surface of an object. The forming the insulating layer forms an insulating layer that is continuous from a surface of the conductive layer to the surface of the object through the plurality of openings and adheres to the surface of the object.

### Advantageous Effects of Invention

According to an embodiment of the present disclosure, the shielding performance and durability of the electromagnetic-wave shield can be enhanced.

### BRIEF DESCRIPTION OF DRAWINGS

A more complete appreciation of embodiments of the present disclosure and many of the attendant advantages and features thereof can be readily obtained and understood from the following detailed description with reference to the accompanying drawings

FIGS. 1A to 1C are explanatory views of an electronic device according to an embodiment of the present disclosure.

FIGS. 2A and 2B are explanatory views of another electronic device according to an embodiment of the present disclosure.

FIGS. 3A and 3B are explanatory views of a method of forming an electromagnetic-wave shield, according to an embodiment of the present disclosure.

FIGS. 4A and 4B are cross-sectional views of an electromagnetic wave shield according to an embodiment of the present disclosure.

FIGS. 5A and 5B are flowcharts illustrating examples of the process of forming an electromagnetic wave shield, according to an embodiment of the present disclosure.

FIGS. 6A and 6B are diagrams illustrating a print pattern A and a print pattern B, respectively, of Table 4 in an electromagnetic-wave shield according to an embodiment of the present disclosure.

FIG. 7 is a diagram illustrating a print pattern C of Table 4 in an electromagnetic-wave shield according to an embodiment of the present disclosure.

FIG. 8 is a diagram illustrating an example of a print pattern D of Table 4 in an electromagnetic-wave shield according to an embodiment of the present disclosure.

FIG. 9 is a diagram illustrating another example of the print pattern D of Table 4 in an electromagnetic-wave shield according to an embodiment of the present disclosure.

FIG. 10 is a diagram illustrating an evaluation method for an effect of an electromagnetic-wave shield according to an embodiment of the present disclosure.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

High reliability has been required for a printed wiring board (PWB) without an electronic component to be used for the fifth generation (5G) as high-speed communication or automatic operation attached on the PWB and a printed circuit board (PCB) in a state of operation as an electronic circuit with an electronic component soldered thereon, and a technique of controlling electromagnetic waves generated from such an electronic component or wiring has been known. In addition, with the miniaturization and weight reduction of products, thinning and weight reduction of PCBs and the like are also needed, and a technique for shielding electromagnetic waves for the PCBs and electronic components used for the PCBs has been known.

That is, as an electromagnetic-wave shield of a structure including an electronic component, such as an integrated circuit (IC) chip, a capacitor, a resistor, a diode, or a solenoid, or a semiconductor package housing an electronic component in an electronic device, a shield film, a metal cap, a conductor such as a conductive coating material, or an electromagnetic-wave absorber is also used for covering such an electric component, semiconductor package, or structure.

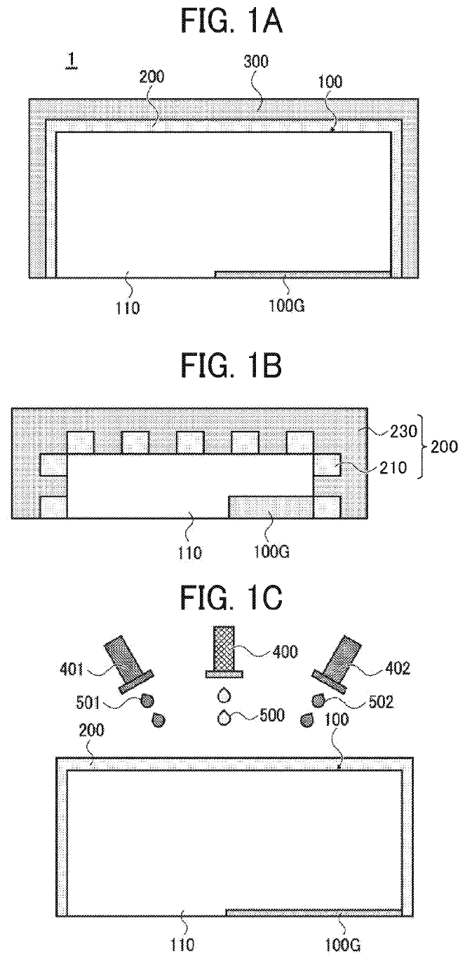

FIGS. 1A to 1C are explanatory views of an electronic device according to an embodiment of the present disclosure.

As illustrated in FIG. 1A, an electronic device 1 includes a semiconductor package 110 having an outer peripheral face 100, a shield layer 200, and a protective layer 300. The shield layer 200 and the protective layer 300 are provided on the outer peripheral face 100. The shield layer 200 is electrically connected to a ground 100G included in the semiconductor package 110. The protective layer 300 may be omitted, or may be integrally formed with the shield layer 200.

As illustrated in FIG. 1B, the shield layer 200 in FIG. 1A includes a conductive layer 210 formed in a predetermined pattern on the upper face and side faces of the outer peripheral face 100 of the semiconductor package 110 as an object, and an insulating layer 230 covering the conductive layer 210.

In the configuration of FIG. 1B, as illustrated in FIG. 1C, for example, an inkjet head 400 that is provided horizontally and an inkjet head 401 and an inkjet head 402 that are provided diagonally to the left and right with respect to the object discharge, respectively, an ink 500, an ink 501, and an ink 502 each containing a conductive material onto the upper face and the side faces of the outer peripheral face 100 of the semiconductor package 110, thereby forming the shield layer 200 on the upper face and the side faces of the outer peripheral face 100.

Here, the inks 500, 501, and 502 are each an exemplary liquid composition containing a conductive material, and the inkjet heads 400, 401, and 402 are each an exemplary applicator that applies the corresponding liquid composition. The shield layer 200 is an exemplary conductive layer.

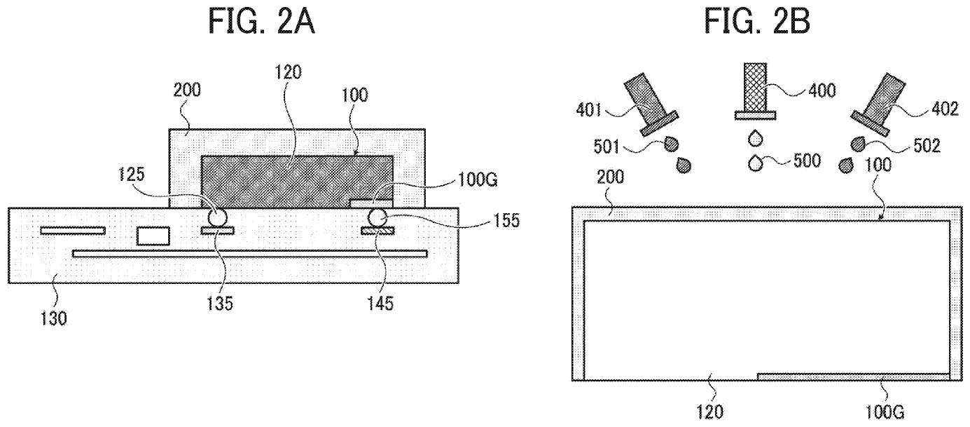

FIGS. 2A and 2B are explanatory views of another electronic device according to the present embodiment.

As illustrated in FIG. 2A, an electronic device 1 includes an electronic component 120 and a substrate 130. The electronic component 120 is provided with a connector 125, and the substrate 130 is provided with wiring 135. The electronic component 120 is attached to the substrate 130, so that the connector 125 is electrically connected to the wiring 135.

The electronic component 120 has an outer peripheral face 100 on which a shield layer 200 is provided. The shield layer 200 is connected to a ground 100G of the electronic component 120. The electronic component 120 is attached to the substrate 130, so that wiring 145 that the substrate 130 is provided with and the ground 100G that the electronic component 120 is provided with are electrically connected through a connector 155. The electronic component 120 is an exemplary electronic module. Alternatively, the shield layer 200 may be provided separately from the electric element component 120. In this case, a structure includes the electronic component 120 and the shield layer 200.

As illustrated in FIG. 2B, in the present embodiment, an inkjet head 400, an inkjet head 401, and an inkjet head 402 discharge, respectively, an ink 500, an ink 501, and an ink 502 each containing a conductive material onto an upper face and side faces of the outer peripheral face 100 of the electronic component 120, thereby forming the shield layer 200 on the upper face and the side faces of the outer peripheral face 100.

Here, an electromagnetic-wave shield formed by direct coating with a conductive material to an electronic component by an inkjetting technique for space saving, weight reduction, and productivity improvement has been already known.

The specification of U.S. Pat. No. 9,282,630 describes an EMI shield in which a conductive layer includes inkjet print. However, there is no mention of no shielding effect due to leakage of noise from side faces of a shield layer or descriptions of a side-face coating film of the shield layer 200 and peeling or cracking of the side-face coating film.

As the volume resistivity of the shield layer 200 is smaller, the shielding effect is higher and the film thickness of the shield layer 200 can be made thinner. In order to form a shield layer 200 small in in volume resistance is formed by, for example, coating, heating is needed.

Here, there have been disadvantages that damage such as peeling or cracking of the shield layer 200 is likely to occur resulting from stress caused by a difference in thermal expansion between the adhesive faces above and below the shield layer 200 due to heat at the time of film formation of the shield layer 200 or at the time of use of the electronic device 1 and that the adhesive strength of the shield layer 200 itself is originally insufficient and durability as a film at the time of thinning is poor.

An object of the present embodiment is to reduce leakage of noise from a side face of the shield layer 200 and peeling and cracking of the side face of the shield layer 200. More specifically, an object of the present embodiment is to improve an effect of shielding a conductive layer as an electromagnetic-wave shield layer directly formed on an electronic component by an inkjetting technique, improve physical durability of the shield layer by improvement of adhesion strength, reduce weight by thinning of the conductive layer, and save resources by pattern coating of the conductive layer.

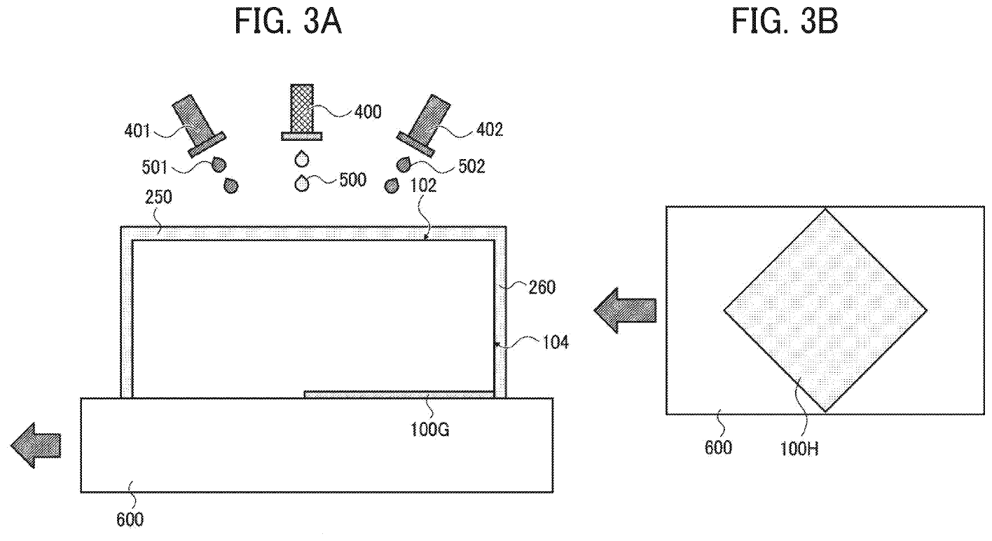

FIGS. 3A and 3B are explanatory views of a method of forming the electromagnetic-wave shield according to the present embodiment.

As illustrated in FIG. 3A, the inkjet head 400 is disposed so as to discharge the ink 500 in a normal direction of the upper face 102 of the outer peripheral face 100 of a base material, and the inkjet heads 401 and 402 are disposed on the left and right in the figure with the inkjet head 400 as the center and are inclined with respect to the inkjet head 400 so as to discharge the inks 501 and 502 in a direction intersecting an upper face 102 and side faces 104 of the outer peripheral face 100. Here, because the location of landing on the outer peripheral face 100 varies depending on the environment such as temperature and air flow, the inkjet heads 401 and 402 may not be disposed line-symmetrically with respect to the figure with the inkjet head 400 as the center.

With a placement table 600 moving in the direction of the arrow in the figure, the inkjet heads 400, 401, and 402 apply the inks 500, 501, and 502 to the outer peripheral face 100 disposed on the placement table 600, thereby forming a shield layer 250 on the upper face 102 of the outer peripheral face 100 and forming a shield layer 260 on the side faces 104 of the outer peripheral face 100.

FIG. 3B illustrates an object disposed on the placement table 600 as viewed from above. The object is disposed so as to form a rhombus 100H with respect to the placement table 600.

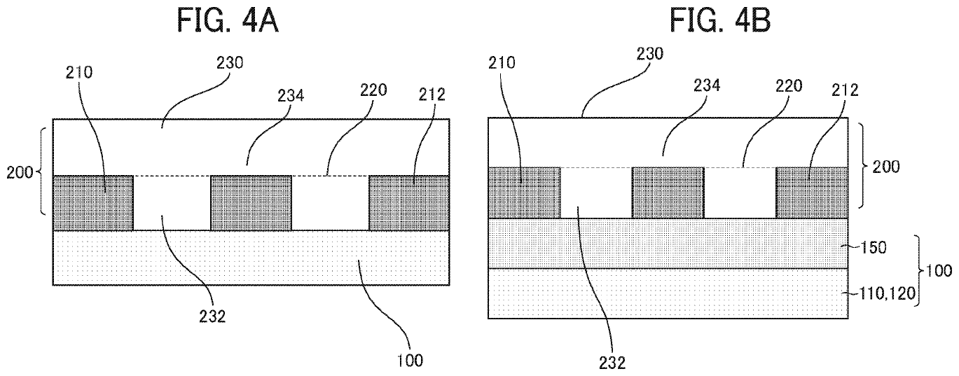

FIGS. 4A and 4B are cross-sectional views of the electromagnetic-wave shield according to the present embodiment.

The shield layer 200 of the present embodiment includes at least the conductive layer 210 that reflects electromagnetic waves and an insulating layer 230 that protects the conductive layer 210 and has insulating properties. The insulating layer 230 may be provided as the protective layer 300 illustrated in FIG. 1A to FIG. 2B. The conductive layer is electrically connected to the ground 100G described in FIGS. 1A to 2B. In a case where the electronic circuit component as a target has a conductor connected to an electronic circuit other than the ground 100G, an undercoat layer 150 made of an insulating resin is provided and a conductive layer and an insulating layer are provided in this order on the undercoat layer 150 to ensure insulation.

In FIG. 4A, the conductive layer 210 included in the shield layer 200 is provided on the upper face and the side faces of the outer peripheral face 100 of the base material, and the conductive layer 210 has a plurality of openings 220.

The insulating layer 230 included in the shield layer 200 includes a cover 234 covering a column 212 of the conductive layer 210 having a plurality of the openings 220 and a filler portion 232 continuous with the cover 234 with the plurality of the opening 220 filled with the filler portion 232, the insulating layer 230 adhering to the outer peripheral face 100 through the filler portion 232.

In FIG. 4B, the outer peripheral face 100 includes the insulating undercoat layer 150 on the surface of the semiconductor package 110 or the electronic component 120, the conductive layer 210 included in the shield layer 200 is provided on the surface of the undercoat layer 150, and the conductive layer 210 has the plurality of openings 220.

The insulating layer 230 included in the shield layer 200 includes the cover 234 covering the column 212 of the conductive layer 210 having the plurality of openings 220 and the filler portion 232 continuous with the cover 234 with the plurality of the openings 220 filled with the filler portion 232, the insulating layer 230 adhering to the surface of the undercoat layer 150 through the filler portion 232.

As described above, in the present embodiment, the conductive layer 210 is sandwiched between the cover 234 and the outer peripheral face 100 of the base material or the surface of the undercoat layer 150 integrated with the filler portion 232, thereby reducing peeling and cracking of the shield layer 200.

The conductive layer 210 of the present embodiment is 10 μm or less in thickness. This is because the effect of the electromagnetic shield is sufficient with the thickness of 1 μm or less and a larger thickness increases the cost. In the inkjet coating method, the amount of coating can be adjusted freely. Thus, even if the outer peripheral face 100 of the base material (electronic board) has irregularities, the conductive layer 210, the shield layer 200, and the filler portion 232 are hardly changed in thickness. Thus, the sufficient shielding effect and adhesiveness can be maintained.

Further, the solid content of each ink containing the conductive material for forming the conductive layer 210 is 50% or less, which makes it difficult to form an oblique shape with a thin film thickness.

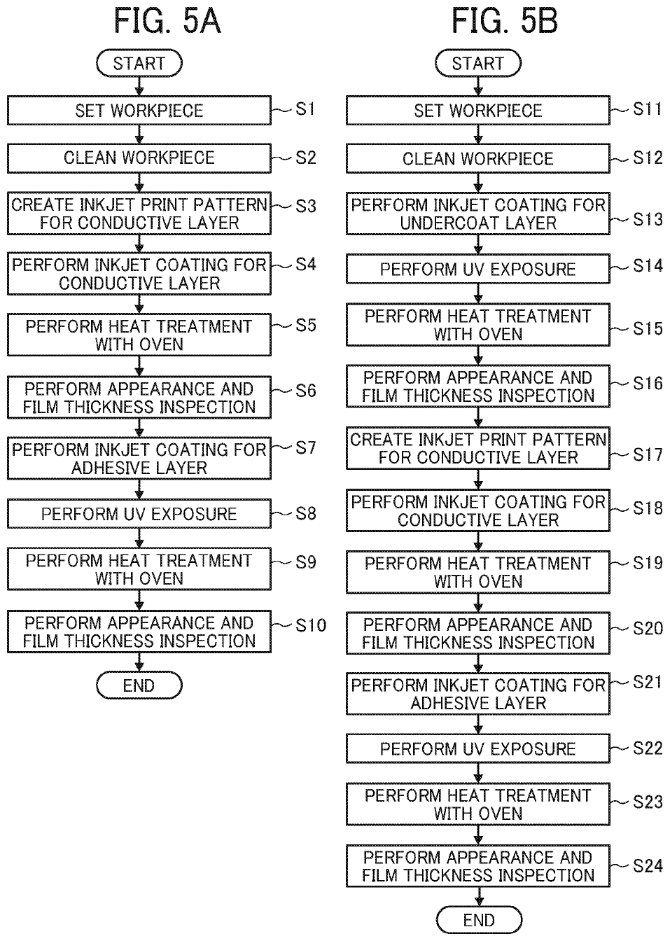

FIGS. 5A and 5B are explanatory flowchart of forming the electromagnetic-wave shield according to the present embodiment. FIG. 5A illustrates a method of forming the shield layer 200 in FIG. 4A.

First, a base material having an outer peripheral face 100 is set as a workpiece in an inkjet device (step S1), and then the workpiece is cleaned (step S2). As an example of cleaning the workpiece, air blow cleaning by air pressure is used, but general organic solvents (e.g., alcohols), adhesive roller cleaning by adhesion, or plasma cleaning may be utilized.

Next, an inkjet print pattern is created for a conductive material (step S3). In the inkjet print pattern creating, a continuous print pattern of the conductive layer connected to the ground is created according to the outer peripheral face 100 of the base material on which the electromagnetic-wave shield is to be provided.

Then, as described in FIGS. 3A and 3B, the inkjet head 400 applies the ink 500 containing the conductive material to the upper face 102 of the outer peripheral face 100 of the base material placed on the placement table 600 (step S4), and then the conductive material is thermally cured to form the conductive layer 210 (step S5).

Here, the application of the ink 500 in step S4 is performed on the inkjet print pattern created in step S3. In step S5, the volume resistance of the conductive layer is decreased by heating.

In step S5, the base material having the outer peripheral face 100 may be heated before the application, or may be subjected to a heating batch treatment after the application. In order to obtain the stability of the volume and speed of the droplets discharged at the time of inkjet application, the inkjet head and the ink supply system may be heated to control the viscosity of the ink 500.

Next, an appearance and film thickness inspection is performed for a film state such as the coating film location and the film thickness of the conductive layer 210 (step S6).

Then, as described in FIGS. 3A and 3B, the inkjet head 400 applies the ink 500 containing the insulating material onto the upper face 102 of the outer peripheral face 100 of the base material placed on the placement table 600 (step S7). The insulating material is cured by ultraviolet (UV) exposure (step S8), and then the insulating material is thermally cured to form the insulating layer 230 (step S9).

Finally, an appearance and film thickness inspection is performed for a film state such as the coating film location and the film thickness of the insulating layer 230 (step S10).

Here, in a case where no print pattern is needed for the insulating layer 230, another technique such dispensing or spraying may be used for coating in step S7.

In a case where an insulating material containing a UV curable resin is applied, UV light irradiation is performed immediately after the coating, which enables suppression of fluidity of the ink and coating with the ink at a desired location with a desired film thickness without waste. In the case of UV light irradiation, UV light irradiation may be performed on batch treatment after the application, or UV light irradiation may be performed while inkjet printing is performed by an inkjet head including a UV lamp or a light-emitting diode (LED).

An insulating material containing a thermally curable resin is heated and cured, thereby forming an electromagnetic-wave shield more excellent in adhesion, toughness, and durability. In the heating, the base material having the outer peripheral face 100 may be heated before the ink is applied, or heating batch treatment may be performed after the ink is applied.

FIG. 5B illustrates a method of forming the shield layer 200 in FIG. 4B. Because steps S11, S12, and S17 to S24 in FIG. 5B are similar to steps S1 to S10 in FIG. 5A, description thereof is not given, and steps S13 to S16 will be described below.

After step S12, the inkjet head 400 applies the ink 500 containing the insulating material onto the surface of the semiconductor package 110 or the electronic component 120 placed on the placement table 600 (step S13). The insulating material is cured by UV exposure (step S14), and then the insulating material is thermally cured to form the undercoat layer 150 (step S15).

Then, an appearance and film thickness inspection is performed on a film state such as the coating film location and the film thickness of the undercoat layer 150 (step S16).

In a case where no print pattern is needed for the undercoat layer 150, another technique such dispensing or spraying may be used for coating in step S13.

In a case where an insulating material containing a UV curable resin is applied, UV light irradiation is performed immediately after the coating, which enables suppression of fluidity of the ink and coating with the ink at a desired location with a desired film thickness without waste. In the case of UV light irradiation, UV light irradiation may be performed on batch treatment after the application, or UV light irradiation may be performed while inkjet printing is performed by an inkjet head including a UV lamp or a light-emitting diode (LED). In the present embodiment, layer formation can be made with high accuracy by inkjet printing and light irradiation regardless of the size of an object and the unevenness of the surface. Further, the shield layer including the conductive layer can be partially modified in configuration to have a plurality of configurations.

An insulating material containing a thermally curable resin is heated and cured, thereby forming an electromagnetic-wave shield more excellent in adhesion, toughness, and durability. In the heating, the semiconductor package 110 or the electronic component 120 may be heated before the ink is applied, or heating batch treatment may be performed after the ink is applied.

### Examples Conductive Layer

The conductive layer 210 is formed by inkjet printing with a metal nanoparticle ink (e.g., Smart Jet I manufactured by GenesInk, SR7000 manufactured by Bando, IJ100E manufactured by Future Ink Corporation, and I40DM manufactured by Pvnancell) or an organometallic ink (TC-IJ-010 manufactured by InkTec Co., Ltd.; and EI-1208 manufactured by Electronik). A pattern having a non-printed portion with a minimum size that is continuously connected in an area direction and functions as an electromagnetic-wave shield is formed, and then inkjet printing is performed.

The major axis of the non-printed opening in the inkjet print pattern of the conductive layer 210 has a size of 1 to 2000 μm.

A high-frequency electromagnetic wave cannot be shielded with a larger opening, and the sandwich adhesion effect by the insulating layer is weakened with a smaller opening. Thus, the durability of the shield layer due to the thermal history is deteriorated, so that the major axis of the opening is preferably 5 to 1500 μm, more preferably 10 to 1000 μm.

An electromagnetic wave shield that is to be used for a touch panel and a display screen and that has a meshed conductive layer with the opening area ratio of 40% or more for translucency may be used. In the present embodiment, however, an electromagnetic-wave shield is formed onto a component that generates an electromagnetic wave. An object of the present embodiment is to achieve a highly-durable electromagnetic-wave shield that can shield a high-frequency electromagnetic wave by reducing the opening area ratio of the electromagnetic wave shield.

A highly-durable electromagnetic shield layer corresponding to high frequencies can be achieved by forming a conductive layer in a continuous print pattern and providing an insulating layer on the conductive layer having any long diameter of an opening with the opening area ratio of less than 1 to 50%, more preferably less than 3 to 40%.

As long as the inkjet print pattern of the conductive layer is continuously connected in the area direction and connected to the ground like, for example, a mesh structure or an error-diffusion dithering pattern, both a shielding effect and an increase in adhesion strength due to the sandwich between the insulating layer and the base can be obtained with a pattern having any shape.

Regarding the shielding property, a pattern having such a dithered shape resulting from error diffusion with less periodicity has less shield leakage at a specific wavelength than a pattern having such a mesh structure with strong periodicity. Different conductive-layer print patterns may be combined in the same electromagnetic-wave shield according to the electromagnetic wave frequency and electromagnetic wave intensity to be shielded.

It is preferable to apply any conductive-layer print pattern to any place and to a portion having irregularities of 5 mm or less by inkjet printing.

After inkjet printing, the metal nanoparticle ink or the organometallic ink are heated to have a volume resistivity of 10e⁻³ Ω·cm or less, and become a conductive layer that sufficiently reflects electromagnetic waves.

When the metal particles are reduced to 100 nm or less, the melting point is lower in melting point than the bulk of the metal. Thus, when the metal nanoparticle ink is heated, the ink solvent is volatilized and the metal nanoparticles are concentrated. Further, the respective surfaces of the metal nanoparticles are melted and sintered at a temperature lower than the temperature of the bulk metal resulting from a decrease in melting point due to nanoparticle-forming. As a result, a conductive bus is formed and the volume resistivity of the conductive layer is reduced.

The metal nanoparticle ink is fired by reflecting the concentrated state in which the solvent volatilizes after the coating. Thus, it is desirable to uniformly coat with the metal nanoparticle ink in a thin film and volatilize the solvent. For thin and uniform coating, an inkjet printing method enabling uniform the ink particle diameter is more excellent than a spraying method having a wide ink-particle distribution at the time of coating.

Heating conditions after inkjet printing are 80 to 180° C. and 10 to 60 min. When the volume resistivity of the conductive layer is further smaller than 10e⁻⁵ Ω·cm, an electromagnetic wave is more easily reflected, so that the film thickness of the conductive layer can be reduced. As the metal nanoparticles, Au, Ag, or Cu can be used. As the organometallic ink, metal salts such as Ag and Cu can be used.

When the conductive layer is made thick, the conductive layer is easily cracked during film formation. When the conductive layer is made too thin, the shielding property is deteriorated due to the skin effect resulting from electromagnetic-wave reflection. Thus, the thickness of the conductive layer is 0.01 to 20 μm, more preferably 0.05 to 10 μm. The thinning of the conductive layer leads to weight reduction of the shield layer and resource saving of the metal material.

### Insulating Layer and Undercoat Layer

As the insulating ink for the insulating layer and the undercoat layer, used can be UV curable and/or thermally curable type insulating inks such as PR-1258 (UV curable and thermally curable type) manufactured by GOO CHEMICAL CO., LTD.; IJSR4000 (UV curable and thermally curable type) manufactured by TAIYO INK; PA-1210-35 (UV curable type) manufactured by JNC Corporation.

### Insulating Layer

The insulating layer is formed by coating on the patterned conductive layer. The insulating layer adheres to the base, the electronic component or the undercoat layer through the opening of the conductive layer, and adheres in a sandwich-like manner including the conductive layer, thereby improving the adhesive strength of the conductive layer.

The insulating layer is formed on the conductive layer by a coating method such as inkjet printing, spraying, or dispensing. When the opening of the conductive layer is fine, it is disadvantageous in that the opening is filled with the insulating layer. However, by inkjet printing, it is easy that the opening is filled with the insulating layer, with an ink excellent in fluidity.

The insulating layer is preferably one good in adhesiveness with a base or an undercoat layer, and is preferably a coating material excellent in mechanical strength and heat resistance and containing a UV curable or thermally curable resin. A constituent component of the insulating layer is preferably a thermally curable resin in order to secure adhesiveness with the base or the undercoat layer, more preferably, a thermally curable epoxy-based resin. Further, such a constituent component of the insulating layer is preferably a UV curable resin in order to prevent wet-spreading of the coating material after coating for the insulating layer.

In a case where the insulating layer is composed of both components of a thermally curable resin and a UV curable resin, both wet spreading prevention and adhesion strength with the base or the undercoat is achievable by UV light irradiation and heating, and durability of the shield layer is improved, thereby enabling the precise alignment between the shield layer and the electronic-circuit constituent elements.

In a case where the insulating layer contains a thermally curable resin and a UV curable resin curable resin, the curing conditions include UV light irradiation of 100 to 2000 mJ/cm², heating at 130 to 180° C., and 10 to 60 min.

### Undercoat Layer

In a case where the target electronic-circuit constituent element has a conductor connected to an electronic circuit other than the ground connector, an undercoat layer made of an insulating resin is provided and a conductive layer and an insulating layer are provided in this order on the undercoat layer to ensure insulation.

The undercoat layer is formed on the electronic circuit constituent element by a coating method such as inkjet printing, spraying, or dispensing.

The undercoat layer needs to have adhesiveness with an electronic circuit constituent element, the conductive layer, and the insulating layer. Thus, similarly to the insulating layer, the undercoat layer contains preferably a thermally curable resin, more preferably, a thermally curable epoxy-based resin. Further, such an undercoat layer contains preferably a UV curable resin in order to prevent wet-spreading of the coating material after coating for the undercoat layer.

In a case where the undercoat layer is composed of both components of a thermally curable resin and a UV curable resin, both wet spreading prevention and adhesion strength with the base, the conductive layer, and the insulating layer is achievable by UV light irradiation and heating, and the durability of the shield layer is improved, thereby enabling the precise alignment between the shield layer and the electronic circuit constituent elements.

In a case where the insulating layer contains a thermally curable resin and a UV curable resin curable resin, the curing conditions include UV light irradiation of 100 to 2000 mJ/cm², heating at 130 to 180° C., and 10 to 60 min.

Table 1 including Table 1-1, Table 1-2, and Table 1-3 indicates the substrate having the outer peripheral face 100, the conductive layer, the insulating layer, and evaluation results in Examples and Comparative Examples of the electromagnetic-wave shield in FIG. 4A.

TABLE 1-1

| | | Conductive layer | | | |
|---|---|---|---|---|---|
| | | | Film thickness | | Heating |
| | Substrate | Ink type | (μm) | Pattern | conditions |
| Example 1 | A | Smart Jet I | 0.5 | A | 150° C., 30 min |
| Example 2 | A | Smart Jet I | 0.5 | B | 150° C., 30 min |
| Example 3 | A | Smart Jet I | 0.5 | C | 150° C., 30 min |
| Example 4 | A | Smart Jet I | 0.5 | D | 150° C., 30 min |
| Example 5 | A | Smart Jet I | 0.05 | D | 150° C., 30 min |
| Example 6 | A | Smart Jet I | 10 | D | 150° C., 30 min |
| Comparative | A | Smart Jet I | 0.5 | E | 150° C., 30 min |
| Example 1 | | | | | |
| Comparative | A | Smart Jet I | 0.5 | E | 150° C., 5 min |
| Example 2 | | | | | |
| Comparative | A | Smart Jet I | 10 | E | 150° C., 30 min |
| Example 3 | | | | | |

TABLE 1-2

| | Insulating layer | | | | |
|---|---|---|---|---|---|
| | | Film | | | |
| | | thickness | Coating | | Thermal curing |
| | Ink type | (μm) | method | UV curing | conditions |
| Example 1 | USR4000 | 5 | Inkjetting | 800 μJ/cm² | 150° C., 30 min |
| Example 2 | USR4000 | 5 | Spin coating | 800 μJ/cm² | 150° C., 30 min |
| Example 3 | USR4000 | 5 | Inkjetting | 800 μJ/cm² | 150° C., 30 min |
| Example 4 | USR4000 | 5 | Spin coating | 800 μJ/cm² | 150° C., 30 min |
| Example 5 | USR4000 | 5 | Inkjetting | 800 μJ/cm² | 150° C., 30 min |
| Example 6 | USR4000 | 5 | Spin coating | 800 μJ/cm² | 150° C., 30 min |
| Comparative | USR4000 | 5 | Inkjetting | 800 μJ/cm² | 150° C., 30 min |
| Example 1 | | | | | |
| Comparative | USR4000 | 5 | Spin coating | 800 μJ/cm² | 150° C., 30 min |
| Example 2 | | | | | |
| Comparative | USR4000 | 5 | Spin coating | 800 μJ/cm² | 150° C., 30 min |
| Example 3 | | | | | |

TABLE 1-3

| | Volume | | Electromagnetic- |
|---|---|---|---|
| | resistivity | Adhesiveness | wave shield effect |
| Example 1 | 10e⁻⁵ Ω, cm | Very Good | Good |
| Example 2 | 10e⁻⁵ Ω, cm | Very Good | Very Good |
| Example 3 | 10e⁻⁵ Ω, cm | Good | Very Good |
| Example 4 | 10e⁻⁵ Ω, cm | Very Good | Good |
| Example 5 | 10e⁻⁵ Ω, cm | Very Good | Good |
| Example 6 | 10e⁻⁶ Ω, cm | Very Good | Very Good |
| Comparative | 10e⁻⁵ Ω, cm | Bad | Poor |
| Example 1 | | | |
| Comparative | 10e⁻² Ω, cm | Bad | Poor |
| Example 2 | | | |
| Comparative | 10e⁻⁵ Ω, cm | Bad | Poor |
| Example 3 | | | |

Table 2 including Table 2-1 and Table 2-2 indicates the substrate having the outer peripheral face 100, the undercoat layer, the conductive layer, the insulating layer, and evaluation results in Examples and Comparative Examples of the electromagnetic-wave shield in FIG. 4B.

TABLE 2-1

| | | Undercoat layer | | | | |
|---|---|---|---|---|---|---|
| | | | Film | | | |
| | | | thickness | Coating | | Thermal curing |
| | Substrate | Ink type | (μm) | method | UV curing | conditions |
| Example 7 | B | GIP- | 10 | Inkjetting | 2000 μJ/cm² | 150° C., 30 min |
| | | 1200 | | | | |
| Example 8 | C | GIP- | 10 | Spin coating | 2000 μJ/cm² | 150° C., 30 min |
| | | 1200 | | | | |
| Example 9 | D | GIP- | 10 | Inkjetting | 2000 μJ/cm² | 150° C., 30 min |
| | | 1200 | | | | |
| Example 10 | E | GIP- | 10 | Spin coating | 2000 μJ/cm² | 150° C., 30 min |
| | | 1200 | | | | |
| Comparative | B | GIP- | 10 | Inkjetting | 2000 μJ/cm² | 150° C., 30 min |
| Example 4 | | 1200 | | | | |
| Comparative | C | GIP- | 10 | Spin coating | 2000 μJ/cm² | 150° C., 30 min |
| Example 5 | | 1200 | | | | |
| Comparative | D | GIP- | 10 | Inkjetting | 2000 μJ/cm² | 150° C., 30 min |
| Example 6 | | 1200 | | | | |
| Comparative | E | GIP- | 10 | Spin coating | 2000 μJ/cm² | 150° C., 30 min |
| Example 7 | | 1200 | | | | |

TABLE 2-2

| | Conductive | | | Electro- |
|---|---|---|---|---|
| | layer and | | | magnetic- |
| | protective | Volume | | wave shield |
| | layer | resistivity | Adhesiveness | effect |
| Example 7 | Example 1 | 10e⁻⁵ Ω · cm | Very Good | Good |
| Example 8 | Example 1 | 10e⁻⁵ Ω · cm | Very Good | Good |
| Example 9 | Example 1 | 10e⁻⁵ Ω · cm | Very Good | Good |
| Example 10 | Example 1 | 10e⁻⁵ Ω · cm | Very Good | Good |
| Comparative | Comparative | 10e⁻⁵ Ω · cm | Bad | Poor |
| Example 4 | Example 1 | | | |
| Comparative | Comparative | 10e⁻⁵ Ω · cm | Bad | Poor |
| Example 5 | Example 1 | | | |
| Comparative | Comparative | 10e⁻⁵ Ω · cm | Bad | Poor |
| Example 6 | Example 1 | | | |
| Comparative | Comparative | 10e⁻⁵ Ω · cm | Bad | Poor |
| Example 7 | Example 1 | | | |

Table 3 indicates the details of substrate types A to E in Table 1 and Table 2.

TABLE 3
Substrate measuring 40 mm per side

| | |
|---|---|
| A | Epoxy resin |
| B | Glass epoxy substrate coated with solder resist |
| C | Poly imide |
| D | Glass epoxy substrate with isolated dots of Cu, each dot |
| | having φ1 mm |
| E | Substrate resulting from solder plating on Cu of Substrate D |

Table 4 indicates the details of print patterns A to E of the conductive layer in Table 1.

TABLE 4
Print pattern

| | |
|---|---|
| A | Mesh (line width 580 μm, pitch 1000 μm, opening area ratio 40%) |
| B | Mesh (line width 125 μm, pitch 100 μm, opening area ratio 20%) |
| C | Dither (opening measure axis 14 μm, opening area ratio 2.8%) |
| D | Dither (opening measure axis 100 μm, opening area ratio 35%) |
| E | Without opening |

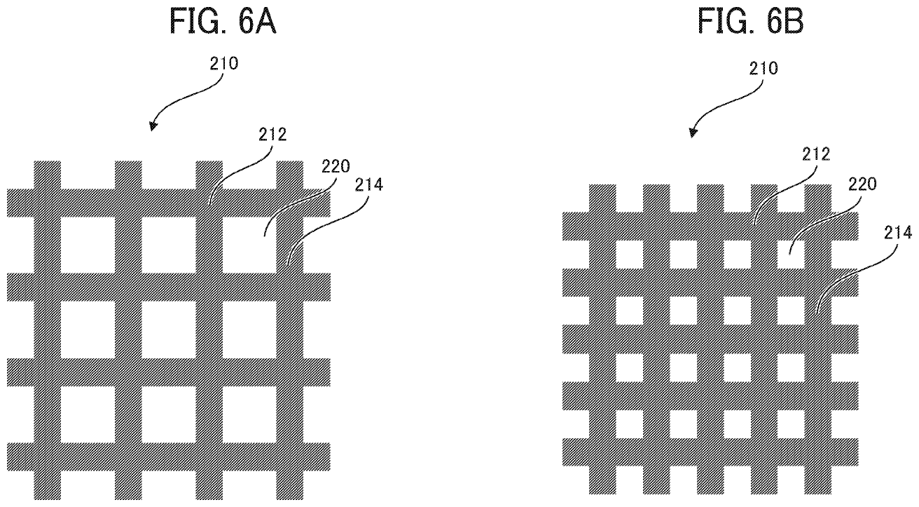

FIGS. 6A and 6B illustrate, respectively, the print pattern A and the print pattern B of Table 4 in the electromagnetic-wave shield according to the present embodiment.

The meshed conductive layer 210 in FIGS. 6A and 6B includes a plurality of linkages 214 that links the columns 212 in FIGS. 4A and 4B, and has a plurality of openings 220 surrounded by the plurality of linkages 214.

In the case of the conductive layer 210 in FIG. 6A, each of the plurality of linkages 214 is 580 μm in width, each of the plurality of opening 220 is 1000 μm×1000 μm, and the opening area ratio is 40%.

In the case of the conductive layer 210 in FIG. 6B, each of the plurality of linkages 214 is 125 μm in width, each of the plurality of openings 220 is 100 μm×100 μm, and the opening area ratio is 20%.

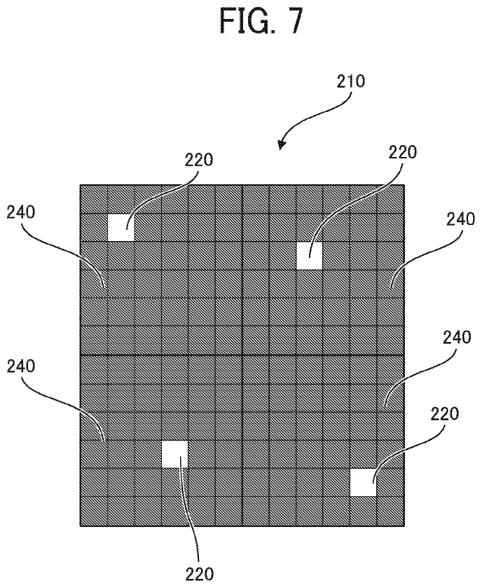

FIG. 7 illustrates the print pattern C of Table 4 in the electromagnetic-wave shield according to the present embodiment.

The dither-shaped conductive layer 210 in FIG. 7 has a plurality of openings 220 disposed uniformly. Each of the plurality of openings 220 is 10 μm×10 μm in size and 14 μm in major axis, and the opening area ratio is 2.8%.

In steps S3 and S17 of FIG. 5, the dither-shaped conductive layer 210 in FIG. 7 is created as a print pattern in combination of four pixels 240 having different in location of an ink non-applied region, with 6×6 dots as one pixel and one dot in each pixel 240 as the ink non-applied region.

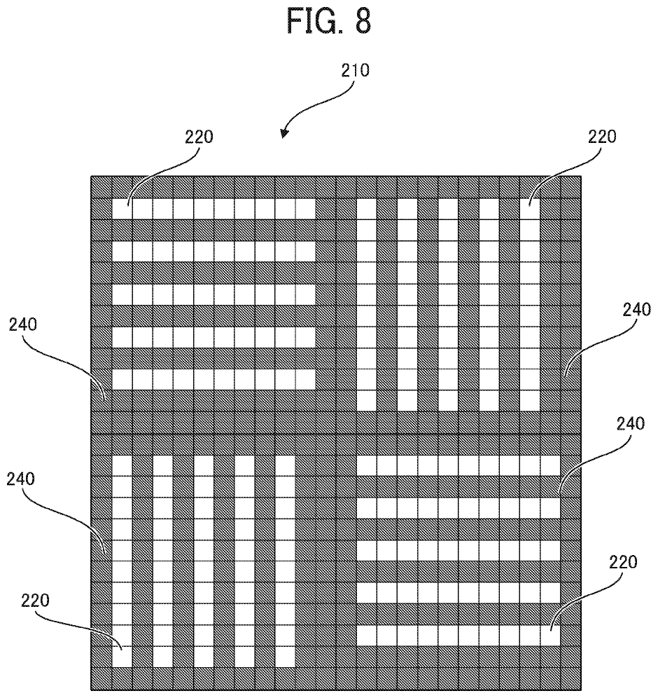

FIG. 8 illustrates the print pattern D of Table 4 in the electromagnetic wave shield according to the present embodiment.

The dither-shaped conductive layer 210 in FIG. 8 has a plurality of openings 220 uninform in orientation. Each of the plurality of opening 220 is 10 μm×100 μm in major axis, and the opening area ratio is 34.7%.

In steps S3 and S17 of FIG. 5, the dither-shaped conductive layer 210 in FIG. 8 is created as a print pattern in combination of four pixels 240 different in orientation of an ink non-applied region, with 12×12 dots as one pixel and 10 dots×5 in each pixel 240 as the ink non-applied region.

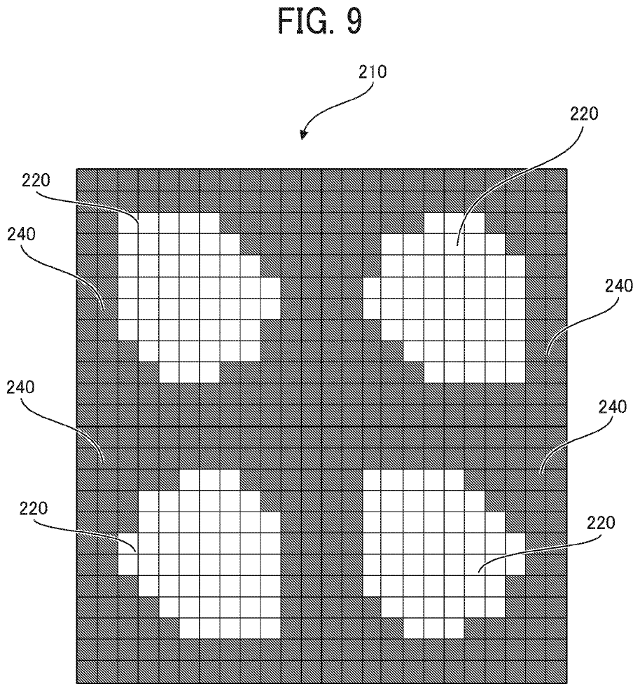

FIG. 9 illustrates another example of the print pattern D of Table 4 in the electromagnetic wave shield according to the present embodiment.

The dither-shaped conductive layer 210 in FIG. 9 has a plurality of openings 220 uninform in orientation. Each of the plurality of opening 220 is 99 μm in major axis, and the opening area ratio is 34.7%.

In steps S3 and S17 of FIG. 5, the dither-shaped conductive layer 210 illustrated in FIG. 9 is created as a print pattern in combination with four pixels 240 different in orientation of an ink non-applied region, with 12×12 dots as one pixel and 50 dots in each pixel 240 as the ink non-applied region.

The conductive layer 210 may have a plurality of openings 220 uninform in size and shape in combination with the print patterns A to D of Table 4.

### Evaluation of Effect of Electromagnetic-Wave Shield

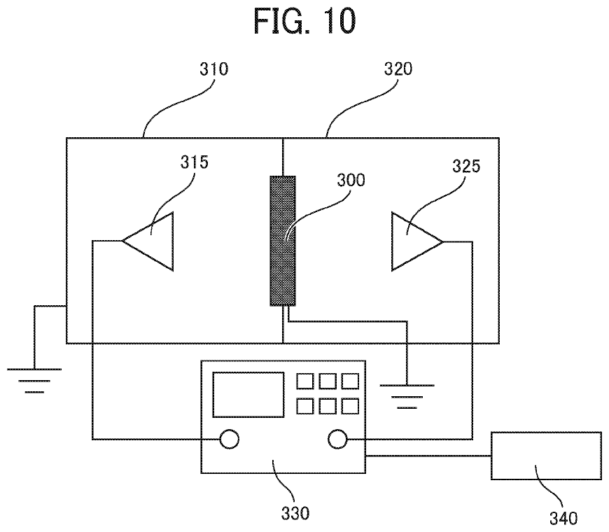

FIG. 10 illustrates an evaluation method for an effect of the electromagnetic-wave shield according to the present embodiment.

As illustrated in FIG. 10, two shield rooms 310 and 320 were prepared, and each test sample 305 fabricated in Examples and Comparative Examples is disposed in the shied rooms 310 and 320. Here, the conductive layer of each test sample 305 was grounded.

Further, the first shield room 310 was provided with a transmission antenna 315 and the second shield room 320 was provided with a reception antenna 325. The transmission antenna 315 and the reception antenna 325 were connected to measuring an instrument 330. Each double ridged guide horn antenna manufactured by EMCO was used for the transmission antenna 315 and the reception antenna 325. A vector network analyzer (37147A) manufactured by ANRITSU CORPORATION was used for the measuring instrument 330.

An electromagnetic wave was transmitted from the transmission antenna 315 to perform measurement at a frequency of 1 to 10 GHz. The measurement result was processed by a personal computer (PC) 340, and the effect of the electromagnetic-wave shield was evaluated on the basis of the attenuation rate of the electromagnetic wave.

Very good: The electromagnetic wave has an attenuation rate of 30 dB or more.

Good: The electromagnetic wave has an attenuation rate of 20 dB or more and less than 30 dB.

Poor: The electromagnetic wave has an attenuation rate of 10 dB or more and less than 20 dB.

Bad: The electromagnetic wave has an attenuation rate of less than 10 dB.

### Evaluation of Volume Resistivity of Conductive Layer

The test samples fabricated in Examples and Comparative Examples were each measured by a four-terminal method with Loresta GP (manufactured by Mitsubishi Chemical Analytech Co., Ltd.).

### Heat Cycle Load Applying Method

The test samples fabricated in Examples and Comparative Examples were each repeatedly subjected to 10° C.=>100° C. and 100° C.=>10° C. (temperature rise and temperature decrease at one-hour interval) 50 times in a thermostatic bath that can temperature-control the test samples fabricated in Examples and Comparative Examples.

### Evaluation of Adhesiveness (Cross Cut)

The test samples prepared in Examples and Comparative Examples were each scratched with a cutter so as to form 1 mm per side and 100 grids. A tape manufactured by NICHIBAN Co., Ltd. Was attached each of the test samples. The tape was peeled perpendicularly to the sample surface, and then the number of grids left in the sample was evaluated.

Very good: 75 or more grids are left in the sample.

Good: 50 or more and less than 75 grids are left in the sample.

Poor: 25 or more and less than 50 grids are left in the sample.

Bad: Less than 25 grids are left in the sample.

### Fabrication of Examples 1 to 6 and Comparative Example 1 to 3

### Without Undercoat Layer

On each substrate measuring 40 mm per side in Table 3, a conductive material was inkjet printed with the corresponding print pattern in Table 4 and the corresponding film thickness in Table 1, and subjected to a heat treatment to provide a conductive layer. The corresponding insulating-layer ink in Table 1 was applied onto the conductive layer with the corresponding film thickness and technique (spin coating or inkjet printing) in Table 1, and subjected to UV curing and/or thermally curing under the corresponding conditions in Table 1 to fabricate each test sample of Examples 1 to 6 and Comparative Examples 1 to 3.

Adhesiveness (cross-cut) was evaluated after application of a heat cycle load to each of fabricated test samples. Further, the effect of the electromagnetic shield was evaluated by the evaluation method in FIG. 10 with each of the test samples of Examples and Comparative Examples, and the results in Table 1 were obtained.

The volume resistivity of the conductive layer was separately measured for a sample prepared as below. Such a conductive layer was formed in a manner similar to the manner in Examples and Comparative Examples described above except that the conductive layer was provided with the entire face printed without an opening, instead of pattern printing with an opening on a glass substrate, and the volume resistivity was measured by the evaluation method described later. Table 1 also indicates the results.

In any test sample of Comparative Examples 1 to 3, the adhesiveness was poor. Due to the poor adhesiveness, part of the conductive layer was damaged or peeled off, and the function of the conductive layer was impaired. Thus, the effect of the electromagnetic-wave shield was not good.

### Fabrication of Examples 7 to 10 and Comparative Examples 4 to 7

### With Undercoat Layer

Each undercoat-layer ink in Table 2 was applied onto the corresponding substrate measuring 40 mm per side in Table 3 with the corresponding film thickness and technique (spin coating or inkjet printing) in Table 2, and subjected to UV curing and/or thermally curing under the corresponding conditions in Table 2 to fabricate an undercoat layer. Each conductive layer and each insulating layer were formed on the corresponding undercoat layer in a manner similar to the manner in Example 1 and Comparative Example 1 in Table 1 to fabricate each test sample of Examples 7 to 8 and Comparative Examples 4 to 5.

Adhesiveness (cross-cut) was evaluated after application of a heat cycle load to each of fabricated test samples.

Further, the effect of the electromagnetic shield was evaluated by the evaluation method described later with each of the test samples of Examples and Comparative Examples. Table 2 indicates the results.

The volume resistivity of the conductive layer was separately measured for a sample prepared as below. Such a conductive layer was formed in a manner similar to the manner in Examples and Comparative Examples described above except that the conductive layer was provided with the entire face printed without an opening, instead of pattern printing with an opening on a glass substrate, and the volume resistivity was measured by the evaluation method described later. Table 2 also indicates the results.

In any test sample of Comparative Examples 4 to 7, the adhesiveness was poor. Due to the poor adhesiveness, part of the conductive layer is damaged or peeled off, and the function of the conductive layer was impaired. Thus, the effect of the electromagnetic-wave shield was not good.

### Aspect 1

As described above, a method of forming a shield layer 200 according to an embodiment of the present disclosure, the method includes: forming a conductive layer 210 having a plurality of openings 220 onto an upper face 102 and a side face 104 of an outer peripheral face 100 of a base material; and forming an insulating layer 230 that is continuous from a surface of the conductive layer 210 to the outer peripheral face 100 of the base material at the plurality of openings 220 and adheres to the outer peripheral face 100 of the base material.

Here, the shield layer 200 is an example of an electromagnetic-wave shield, the outer peripheral face 100 of the base material is an example of a surface of an object, and the shield layer is an example of the conductive layer 210.

Thus, the conductive layer 210 is sandwiched between a cover 234 and the outer peripheral face 100 of the base material integrated through a filler portion 232, thereby reducing peeling and cracking on the upper face 102 and the side face 104 of the shield layer 200.

### Aspect 2

According to Aspect 1, the forming the conductive layer includes discharging, with an inkjet head 400, an inkjet head 401, and an inkjet head 402, respectively, an ink 500, an ink 501, and an ink 502 each containing a conductive material onto the upper face 102 and the side face 104 of the outer peripheral face 100 of the base material to form the conductive layer 210 having the plurality of openings 220. Here, the inkjet heads 400, 401, and 402 are each an example of an applicator, and the inks 500, 501, and 502 are each an example of a liquid composition.

### Aspect 3

According to Aspect 2, the forming the conductive layer includes applying, with the inkjet heads 401 and 402, the inks 501 and 502 in a direction intersecting the upper face 102 and the side face 104 of the outer peripheral face 100 of the base material. Thus, the conductive layer 210 can be reliably formed on the entire side face 104 of the outer peripheral face 100 of the base material.

### Aspect 4

According to any of Aspects 1 to 3, the forming the conductive layer 210 includes forming the plurality of openings 220 uninform in at least one of size, shape, orientation, and arrangement. Thus, shield leakage of a specific wavelength can be reduced.

### Aspect 5

According to any of Aspects 1 to 4, the method further includes discharging, the ink 500 with the inkjet head to form a pattern, before the forming the conductive layer 210. Thus, the conductive layer 210 can be formed in any pattern.

### Aspect 6

According to any of Aspects 1 to 5, the method further includes heating the conductive layer 210 to lower a volume resistivity of the conductive layer 210. Thus, even if the conductive layer 210 is made thin, the shielding effect of the shield layer 200 can be improved.

### Aspect 7

According to any of Aspects 1 to 6, the method further includes forming an undercoat layer 150 having an insulating property onto the outer peripheral face 100 of the base material, in which the forming the conductive layer 210 includes forming the conductive layer 210 onto a surface of the undercoat layer 150, and the forming the insulating layer 230 includes forming the insulating layer 230 continuous from the surface of the conductive layer 210 to the surface of the undercoat layer 150 through the plurality of openings 220.

Thus, the conductive layer 210 is sandwiched between a cover 234 and the surface of the undercoat layer 150 integrated through the filler portion 232, thereby peeling and cracking of the shield layer 200 can be reduced.

### Aspect 8

According to any of Aspects 1 to 7, the method further includes curing at least one of the insulating layer 230 and the undercoat layer 150 by at least one of UV irradiation and heating.

Thus, the adhesive strength between the insulating layer 230 and the outer peripheral face 100 of the base material can be improved, thereby peeling and cracking of the shield layer 200 can be further reduced.

### Aspect 9

A method of manufacturing a structure comprising an electronic component 120 according to an embodiment of the present disclosure includes the method according to any of Aspect 1 to Aspect 8.

### Aspect 10

A structure according to an embodiment of the present disclosure includes: a shield layer 200 including: a conductive layer 210 having a plurality of openings 220, the conductive layer 210 being formed by inkjetting on an upper face and a side face of an outer peripheral face 100 of a base material; and an insulating layer 230 including: a cover 234 covering the conductive layer 210; and a filler portion 232 continuous with the cover 234 with the plurality of openings 220 filled with the filler portion 232, the insulating layer 230 adhering to the outer peripheral face 100 of the base material at the filler portion 232.

### Aspect 11

According to Aspect 10, the base material having the outer peripheral face 100 is an electronic component 120 or a semiconductor package 110 that houses the electronic component in the electronic device 1.

### Aspect 12

According to Aspect 10 or Aspect 11, the plurality of openings 220 is uninform in at least one of size, shape, orientation, and arrangement.

### Aspect 13

According to any of Aspects 10 to 12, each of the plurality of openings 220 is 10 to 1000 μm in major axis and is 3 to 40% in area ratio. Thus, inkjetting is suitable for forming an uninform opening 220 or a fine opening 220. Further, inkjetting with an ink excellent in fluidity is suitable in that such a fine opening 220 is filled with the filler portion 232.

### Aspect 14

According to any of Aspects 10 to 13, an undercoat layer 150 having an insulating property is disposed on the outer peripheral face 100 of the base material, the conductive layer 210 is disposed on a surface of the undercoat layer 150, and the insulating layer 230 adheres to the surface of the undercoat layer at the filler portion.

### Aspect 15

In any of Aspects 10 to 14, the conductive layer 210 is 0.05 to 10 μm in thickness.

### Aspect 16

According to any of Aspects 10 to 15, the conductive layer 210 is 10e⁻⁶ to 10e⁻³ Ω·cm in volume resistivity. Thus, inkjetting is suitable for forming the thin conductive layer 210.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

This patent application is based on and claims priority to Japanese Patent Application Nos. 2022-042254, filed on Mar. 17, 2022, and 2022-191226, filed on Nov. 30, 2022, in the Japan Patent Office, the entire disclosure of each of which is hereby incorporated by reference herein.

### REFERENCE SIGNS LIST

1 Electronic device
100 Outer peripheral face
100G Ground
110 Semiconductor package
120 Electronic component
125 Connector
130 Substrate
135 Wiring
150 Undercoat layer
200 Shield layer
210 Conductive layer
212 Column
214 Linkage
220 Opening
230 Insulating layer
232 Filler portion
234 Cover
240 Pixel
300 Protective layer
305 Sample
310 First shield room
315 Transmission antenna
320 Second shield room
325 Reception antenna
330 Measuring instrument
340 PC
400 Inkjet head (example of applicator)
500 Ink (example of liquid composition)
600 Placement table

1. A method of forming an electromagnetic-wave shield, the method comprising:
forming a conductive layer having a plurality of openings onto an upper face and a side face of a surface of an object; and
forming an insulating layer that is continuous from a surface of the conductive layer to the surface of the object through the plurality of openings and adheres to the surface of the object.

2. The method according to claim 1, wherein:
the forming the conductive layer includes discharging, with an applicator, a liquid composition containing a conductive material onto the upper face and the side face of the surface of the object to form the conductive layer having the plurality of openings.

3. The method according to claim 2, wherein:
the forming the conductive layer includes applying, with the applicator, the liquid composition in a direction intersecting the upper face and the side face of the surface of the object.

4. The method according to claim 1, wherein:
the forming the conductive layer includes forming the plurality of openings to be uninform in at least one of size, shape, orientation, and arrangement.

5. The method according to claim 1, further comprising:
discharging a liquid composition with an applicator to form a pattern, before the forming the conductive layer.

6. The method according to claim 1, further comprising:
heating the conductive layer to lower a volume resistivity of the conductive layer.

7. The method according to claim 1, further comprising:
forming an undercoat layer having an insulating property onto the surface of the object,
wherein:
the forming the conductive layer includes forming the conductive layer onto a surface of the undercoat layer, and
the forming the insulating layer includes forming the insulating layer continuous from the surface of the conductive layer to the surface of the undercoat layer through the plurality of openings.

8. The method according to claim 7, further comprising:
curing at least one of the insulating layer and the undercoat layer by at least one of UV irradiation and heating.

9. A method of manufacturing a structure including an electronic component, the method comprising the method according to claim 1.

10. A structure, comprising:
a conductive layer having a plurality of openings, the conductive layer being on an upper face and a side face of a surface of an object;
a cover covering the conductive layer; and
an insulating layer having a filler portion continuous with the cover, the plurality of openings filled with the filler portion, the insulating layer adhering to the surface of the object at the filler portion.

11. The structure according to claim 10, wherein:
the object is an electronic component or a package that houses the electronic component.

12. The structure according to claim 10, wherein:
the plurality of openings is uninform in at least one of size, shape, orientation, and arrangement.

13. The structure according to claim 10, wherein:
each of the plurality of openings is 10 to 1000 μm in major axis and is 3 to 40% in area ratio.

14. The structure according to claim 10, wherein:
an undercoat layer having an insulating property is disposed on the surface of the object, the conductive layer is disposed on a surface of the undercoat layer, and the insulating layer adheres to the surface of the undercoat layer at the filler portion.

15. The structure according to claim 10, wherein:
the conductive layer is 0.05 to 10 μm in thickness.

16. The structure according to claim 10, wherein:
the conductive layer is 10e⁻⁶ to 10e⁻³ Ω·cm in volume resistivity.
